(19) United States
(12) Patent Application Publication
(10) Pub. No.: US 2021/0123133 A1
(43) Pub. Date: Apr. 29, 2021

(54) METAL WIRE WITH ANTI-CORROSIVE COATING AND INSTALLATION AND METHOD FOR COATING A METAL WIRE

(71) Applicant: OFFICINE MACCAFERRI S.P.A., Zola Predosa (BO) (IT)

(72) Inventor: Francesco FERRAIOLO, Ca' de' Fabbri (BO) (IT)

(21) Appl. No.: 17/254,589

(22) PCT Filed: Jun. 20, 2019
(86) PCT No.: PCT/IB2019/055202

§ 371 Date: Dec. 21, 2020

(30) Foreign Application Priority Data
Jun. 22, 2018 (IT) 102018000006582

(51) Int. Cl. C23C 14/56; H01J 37/32; C23C 14/30; C23C 14/16

(52) U.S. Cl. CPC C23C 14/562; H01J 37/3277; H01J 37/32899; H01J 2237/332; C23C 14/30; C23C 14/16; C23C 14/564

(57) ABSTRACT

An installation for continuously coating wires by means of plasma deposition includes at least one plasma deposition chamber having a pressure-tight inlet and a pressure-tight outlet which are capable of maintaining a reduced pressure inside the chamber when they are passed through by a wire which travels through the chamber. At least one generator of plasma rays is provided in the chamber for the deposition of a target material on the external surface of the wire in a portion thereof which is between the pressure-tight inlet and the pressure-tight outlet. A transport system is provided in the installation in order to progressively draw the wire through the plasma deposition chamber.

### FIELD OF THE INVENTION

The present invention relates to a metal wire which is protected with an anti-corrosive coating. The invention also relates to an installation and a method for protecting a metal wire with an anti-corrosive coating.

The invention has been developed with particular reference to a metal wire which is protected with an anti-corrosive coating which is produced using the plasma deposition method. The invention particularly also relates to the installation and method which are suitable for coating the wire. The invention has been developed with particular regard to the plasma deposition method by means of PPD technology (Pulsed Plasma Diffusion).

### TECHNOLOGICAL BACKGROUND

It is known to produce metal wire, for example, from steel, which is used to manufacture metal nets for various uses, for example, for use in the field of civil construction for protecting banks, slopes, etc. In order to avoid corrosion of the steel wire, there is often provision for it to be protected by means of an anti-corrosive coating, for example, by means of zinc-plating. The zinc-plating is brought about normally with a process in the hot state, in which the metal wire is immersed in a molten metal bath. This measure is expensive in terms of energy in order to maintain the coating metal in the molten state. Furthermore, it is difficult to control with precision the thickness of the coating layer which may become thicker than necessary with a resultant waste of coating material.

On the other hand, there are known techniques for coating objects with a layer of material by means of discontinuous plasma deposition processes. In particular, there are known plasma deposition techniques, such as the PPD technology (Pulsed Plasma Deposition). This technology is based on the principle of physical deposition of particles which is found to be advantageous for producing thin coating layers of various types, such as layers of oxides, metals, carbon, etc. PPD technology is described in a number of patent documents, including EP2936538 of Organic Spintronics. The advantages of PPD technology include the substantial deposition speed of the coating layer and the excellent quality of the coating layer in terms of crystallinity, roughness and adhesion. Furthermore, the plasma deposition technology, and in particular the PPD technology, allows a reduction in the use of filler material as a result of the directionality of the plasma ray. These advantages make the plasma deposition technology advantageous in the application of a coating layer to the surfaces of single objects, but the implementations which are known nowadays allow work to be carried out only in a closed chamber, which prevents the use of the technology continuously. Furthermore, all the plasma deposition technologies have the disadvantage of directionality of the plasma ray, with the resultant production of shade zones in the products to be coated, which does not allow the uniform application of a coating to the entire cylindrical surface of a metal wire.

### STATEMENT OF INVENTION

The invention proposes the provision of a novel installation for coating wires, particularly though not exclusively metal wires, by means of plasma deposition in order to overcome the disadvantages of the prior art. In particular, the wire coating installation provides for the use of plasma deposition technology in order to obtain the coating of great lengths of wire in a continuous manner. The wire coating method of the present invention therefore proposes to coat the wires in a continuous manner, with high production speeds and a reduction of waste. This allows a production of great quantities of coated wire with costs and times which are substantially reduced with respect to the wire coating techniques by means of zinc-plating in the hot state or other metal coating techniques which are known in the field.

In order to achieve the objects indicated, the invention also relates to an installation for coating wires having the characteristics set out in the appended claims. The invention also relates to a method for producing coated wires. The invention further relates to a wire coated in this manner.

According to a first aspect, there is described an installation for coating wires by means of plasma deposition. The installation may comprise at least one plasma deposition chamber. The plasma deposition chamber may be provided with an inlet and an outlet. The inlet to and outlet from the chamber may be produced in a pressure-tight manner when they are passed through by a wire which travels through the chamber so as to maintain a predetermined reduced pressure inside the chamber itself. There may be arranged in the chamber at least one generator of plasma rays which may be activated so as to deposit a material which is molecularly powdered and which is produced by an energy flow which strikes a target; the molecularized powder may be deposited on the external surface of the wire which passes into the chamber, that is to say, in a portion of the wire which is between the pressure-tight inlet and the pressure-tight outlet of the chamber. The installation may also be provided with a drawing system which progressively draws the wire through the plasma deposition chamber. The drawing action may be carried out at a constant or variable speed or with portions with a periodic advance spaced out over time.

According to a particular aspect, the installation may comprise at least one decompression chamber upstream of the plasma deposition chamber in order to change from ambient pressure to the reduced pressure which is present in the deposition chamber for the plasma coating. In this manner, the pressure differential immediately upstream and downstream of the plasma deposition chamber may be reduced so that the potential losses of pressure resulting from the presence of the inlet and outlet for the wire can be readily compensated for in the chamber without there being an excessive expenditure of energy. For the purposes of plasma deposition, it is preferable for the reduced pressure inside the chamber not to be subjected to excessively great variations. Preferably, each decompression chamber may be provided with pressure-tight inlets, through which the wire is introduced over the course thereof towards the plasma deposition chamber. Similarly, the installation may comprise at least one compression chamber downstream of the plasma deposition chamber in order to gradually limit the pressure increase from the reduced pressure of the chamber to ambient pressure. Preferably, each compression chamber may provide for respective pressure-tight outlets, through which the wire may progressively be discharged.

According to another aspect, the installation may provide for an oscillation system which allows the oscillation of the wire about the longitudinal axis thereof during the passage thereof through the plasma deposition chamber. In this manner, it is possible to obtain a deposition of target material which is uniform over the surface of the wire, by means of one or more plasma rays which are placed in the plasma deposition chamber. Additionally or alternatively, the installation may provide for an oscillation system which allows the oscillation of one or more generators of plasma rays about the longitudinal axis of the wire during the passage thereof through the plasma deposition chamber.

In a particular embodiment, the installation may comprise three generators of plasma rays which are placed in the plasma deposition chamber. The three generators of plasma rays may be arranged radially spaced apart by 120° about the longitudinal axis of the wire. In this manner, the generators of plasma rays allow the deposition of material from the target on the wire in a rather uniform manner, apart from any potential oscillation of the wire and/or the generators themselves. Furthermore, the arrangement at 120° prevents the plasma rays from striking one of the other generators which are placed in the plasma deposition chamber.

According to another aspect, there is described a method for coating wires by means of plasma deposition. The method may comprise the step of supplying a wire inside at least one plasma deposition chamber from a pressure-tight inlet to a pressure-tight outlet. As indicated above, the pressure-tight inlet and the pressure-tight outlet are capable of maintaining a reduced pressure inside the chamber. During the method, the wire may be progressively pulled through the plasma deposition chamber by means of a drawing system. The method may further comprise the step of activating at least one generator of plasma rays which is placed in the plasma deposition chamber. The activation of the generator of a plasma ray may allow deposition of a material from the target on the external surface of the wire in a portion thereof between the pressure-tight inlet and the pressure-tight outlet of the plasma deposition chamber.

According to a particular aspect, the method may provide for oscillating the wire and/or the at least one generator of plasma rays about the longitudinal axis of the wire during the deposition of the target material on the external surface of the wire. The oscillation allows the production of a uniform deposition of target material on the surface of the wire.

### BRIEF DESCRIPTION OF THE DRAWINGS

Additional advantages and characteristics will be appreciated from the following description of a preferred embodiment with reference to the drawings which are given by way of non-limiting example and in which:

FIG. 1 is a schematic view of an installation for producing wires which are coated by means of plasma deposition technology,

FIG. 2 is a schematic cross-section of the plasma deposition chamber in accordance with the line II-II of FIG. 1.

### DETAILED DESCRIPTION

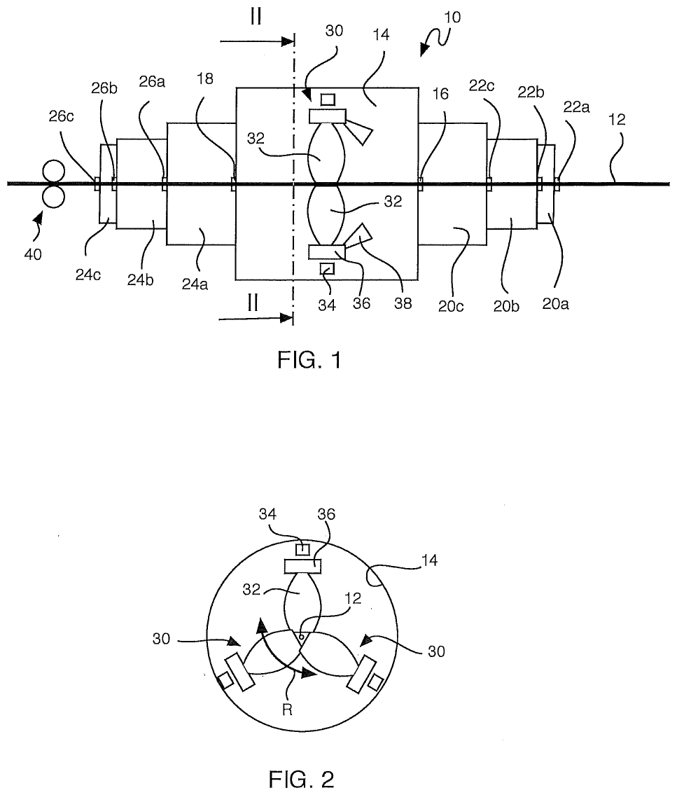

With reference now to FIG. 1, there is schematically illustrated an installation 10 for coating a wire 12, preferably but not exclusively a metal wire, for example, a steel wire or a wire of another metal or metal alloy. Naturally, the installation may be adapted for bringing about the coating of a plurality of wires in a parallel manner. The coating may be a coating of a metal material. For example, the wire 12 may be coated with zinc or zinc alloys.

The installation 10 may comprise a plasma deposition chamber 14 in which the method is carried out for plasma deposition according to generally known characteristics which are described, for example, in the document EP2936538 which is cited above. The chamber 14 may be maintained at a known level of reduced pressure which is suitable for the deposition of plasma. The chamber 14 may be passed through centrally by the wire 12. The wire 12 may be introduced into the chamber 14 through a pressure-tight inlet 16. The wire 12 may be discharged from the chamber 14 via a pressure-tight outlet 18. The pressure-tight inlet 16 may be produced, for example, by means of a membrane with a hole through which the wire 12 passes in a pressure-tight manner. The pressure-tight outlet 18 may also be produced by means of a membrane with a hole through which the wire 12 passes in a pressure-tight manner. Other pressure-tight solutions of the known type may be provided for, alternatively or additionally to the membrane, in order to obtain a pressure-tightness on the wire 12 in the pressure-tight inlet 16 and/or in the pressure-tight outlet 18. For example, there could be provision for a calibrated hole through which the wire 12 passes.

Another solution is that of a labyrinth-like tightness. Other sliding tightness solutions may be used at the pressure-tight inlet 16 and/or the pressure-tight outlet 18.

The pressure-tight inlet 16 and the pressure-tight outlet 18 may allow a reduced pressure to be maintained inside the chamber 14. In each case, the pressure-tight inlet 16 and the pressure-tight outlet 18 may limit the losses of negative pressure inside the chamber 14 in such a manner that the maintenance of a predetermined constant negative pressure requires a reduced supply of energy.

In order to limit the pressure differential between ambient pressure and the reduced pressure of the chamber 14, there may be provided at the inlet side of the wire 12 one or more decompression chambers 20a, 20b, 20c. In the decompression chambers 20a, 20b, 20c, the pressure in a predetermined decompression chamber is greater than the pressure in the following chamber. For example, the pressure in the first decompression chamber 20a is less than atmospheric pressure, but is greater than the pressure in the subsequent decompression chamber 20b. If there is provision for a single decompression chamber, the internal pressure thereof will be less than atmospheric pressure, but greater than the pressure of the plasma deposition chamber adjacent thereto.

Each decompression chamber 20a, 20b, 20c is passed through by the wire 12 which is introduced progressively therein through pressure-tight inlets 22a, 22b, 22c which are identical, equivalent or functionally similar to the pressure-tight inlet 16 of the chamber 14.

Similarly, in order to limit the pressure differential between the reduced pressure of the chamber 14 and ambient pressure, there are provided one or more compression chambers 24a, 24b, 24c. In the compression chamber 24a, 24b, 24c, the pressure in a predetermined pressure chamber is greater than the pressure in the preceding chamber. For example, the pressure in the third compression chamber 24c is greater than the pressure in the second compression chamber 24b. The pressure in the compression chamber 24c is therefore less than atmospheric pressure. If there is provided a single compression chamber, the internal pressure thereof will be less than atmospheric pressure, but greater than the pressure of the plasma deposition chamber adjacent thereto.

Each compression chamber 24a, 24b, 24c is passed through by the wire 12 which is discharged progressively therefrom through pressure-tight outlets 26a, 26b, 26c which are identical, equivalent or functionally similar to the pressure-tight outlet 18 of the chamber 14.

At the outlet of the compression chambers 24a, 24b, 24c, the wire 12 may be drawn by means of a transport system 40 of known type, for example, comprising drawing rollers, pincers, etc. The drawing system of the wire 12 may also be produced, alternatively or additionally to the transport system 40, with other systems or equivalent systems, which are arranged internally with respect to the compression chambers and/or the decompression chambers of the installation and/or inside the plasma deposition chamber 14 and/or upstream of the decompression chambers.

There may be provided in the chamber 14 plasma deposition groups 30. The plasma deposition groups 30 each emit a plasma ray 32. As known, each plasma deposition group 30 may comprise a target 34 of the material which is used to coat the wire 12. Each plasma deposition group 30 may further comprise an annular focusing electrode 36 in which there is conveyed the flow of electrons which are from a transport cone 38, in accordance with a technique which is known and not described herein in detail.

There may be provided around the wire 12, in the chamber 14, one or more plasma deposition groups. Preferably, but in a non-limiting manner, as can be seen in FIG. 2, there may be provided, for example, three plasma deposition groups 30 which are arranged around the wire 12. Each plasma deposition group may be arranged so as not to be struck by a plasma ray of another plasma deposition group. In the specific but non-limiting embodiment of FIG. 2, the three plasma deposition groups 30 are distributed radially at 120° from each other in the chamber 14. The respective plasma rays 32 can be directed radially towards the centre of the chamber 14 and therefore towards the space which exists between the other two plasma deposition groups 30 so as to prevent the deposition of material on another plasma deposition group which is opposite.

The uniformity of deposition of material on the wire 12 is ensured by the spatial distribution of the plasma rays 32 in the chamber 14 which are arranged radially around the wire 12. In order to improve the uniformity of coating on the wire 12, it is possible to impart to the wire 12 itself an oscillation about the individual longitudinal axis thereof, as indicated by the arrow R in FIG. 2. Preferably, in the embodiment illustrated in FIG. 2, there is imparted to the wire 12 a rotational oscillation of approximately 60° during the throughput time of the plasma rays 32 so as to expose the whole of the external surface of the wire 12 to the deposition brought about by a respective plasma ray 32. There may be imparted to the wire 12 a periodic alternating oscillation in the two directions of rotation about the individual longitudinal axis thereof. Alternatively, it is possible to mount the plasma deposition groups 30 on an internal oscillating drum which is concentric with the chamber 14 and to impart the rotational oscillation to the plasma deposition groups 30 and to the wire 12. In a variant, it is possible to reduce the extent of oscillation of the wire 12 and the groups 30 by imparting an oscillation both to the wire 12 and, in the opposite direction, to the plasma deposition groups 30.

In order to coat the wire 12, it is possible to proceed initially by inserting the wire 12 inside the installation 10. The wire 12 may pass through the pressure-tight inlets 22a, 22b, 22c, 16 in order to arrive at the chamber 14. The wire 12 may pass from the chamber 14, through the pressure-tight outlets 18, 26a, 26b, 26c. The wire 12 may be engaged by the transport system 40 for the movement thereof inside the chamber 14. The decompression chambers 20a, 20b, 20c, the compression chambers 24a, 24b, 24c and the chamber 14 can be brought to the predetermined negative reference pressure. Subsequently, one or more plasma deposition groups 30 can be ignited. The transport system 40 can pull the wire 12. The drawing of the wire 12 may be brought about at a constant or variable speed, or with portions in accordance with spaced-apart time periods, in accordance with the characteristics of the installation, of the coating material and the characteristics of the metal wire to be coated. Preferably, the wire 12 and/or the plasma deposition groups 30 can be caused to oscillate about the longitudinal axis of the wire 12 in order to allow the uniform deposition of the coating material on the surface of the wire 12.

There may be provided a number of variants with respect to the installation described above. There may be provided a plurality of plasma deposition chambers. The plasma deposition chambers can be arranged in series in order to carry out a coating with a thickness which is progressively greater and which is formed by a plurality of layers of the same coating material or by a plurality of layers of different coating materials.

There may be less than or more than three plasma deposition groups. For example, there may be provided a single plasma deposition group in the plasma deposition chamber. In that case, it is possible to provide for rotation of the wire and/or the plasma deposition group so as to cover the entire arc of 360° in order to coat the entire external surface of the wire with the coating material.

Before or after the plasma deposition chamber(s), the wire may pass through preparation or finishing work stations, for example, for drawing, pickling, degreasing, washing, varnishing, annealing, quenching, polishing, etc.

Naturally, the principle of the invention remaining the same, the forms of embodiment and details of construction may be varied widely with respect to those described and illustrated, without thereby departing from the scope of the present invention.

1. An installation for continuously coating wires by means of plasma deposition comprising at least one plasma deposition chamber having a pressure-tight inlet and a pressure-tight outlet which are capable of maintaining a reduced pressure inside the chamber when they are passed through by a wire which is introduced from the pressure-tight inlet and which travels through the chamber as far as the pressure-tight outlet, at least one generator of plasma rays being provided in the chamber for the deposition of a target material on the external surface of the wire in a portion thereof which is between the pressure-tight inlet and the pressure-tight outlet, a transport system being provided in order to progressively draw the wire through the plasma deposition chamber.

2. The installation according to claim 1, comprising at least one decompression chamber upstream of the plasma deposition chamber in order to reduce the pressure differential from ambient pressure to the reduced pressure of the chamber.

3. The installation according to claim 1, wherein each decompression chamber is passed through by the wire which is progressively introduced therein through respective pressure-tight inlets.

4. The installation according to claim 1, comprising at least one compression chamber downstream of the plasma deposition chamber in order to reduce the pressure differential between the reduced pressure of the chamber and ambient pressure.

5. The installation according to claim 1, wherein each compression chamber is passed though by the wire which is progressively discharged therefrom via respective pressure-tight outlets.

6. The installation according to claim 1, wherein an oscillation system allows the oscillation of the wire about the longitudinal axis thereof during the passage thereof through the plasma deposition chamber.

7. The installation according to claim 1, wherein an oscillation system allows the oscillation of the at least one generator of plasma rays about the longitudinal axis of the wire during the passage thereof through the plasma deposition chamber.

8. The installation according to claim 1, comprising three generators of plasma rays which are arranged radially spaced apart by 120° about the longitudinal axis of the wire in the plasma deposition chamber.

9. A method for coating wires by means of plasma deposition, comprising the steps of:
supplying a wire inside at least one plasma deposition chamber from a pressure tight inlet to a pressure-tight outlet which are capable of maintaining a reduced pressure inside the chamber, progressively pulling the wire through the plasma deposition chamber with a transport system,
activating at least one generator of plasma rays in the chamber for the deposition of a target material on the external surface of the wire in a portion thereof between the pressure-tight inlet and the pressure-tight outlet.

10. The method according to claim 9, wherein the wire and/or the at least one generator of plasma rays is/are caused to oscillate about the longitudinal axis of the wire during the deposition of the target material on the external surface of the wire.

11. A metal wire which is coated with a protective layer which is obtained via a plasma deposition method.

12. The metal wire according to claim 11, wherein the plasma deposition method is a Pulsed Plasma Deposition (PPD) method.

13. (canceled)

14. (canceled)
